(19) United States
(12) Patent Application Publication
(10) Pub. No.: US 2025/0076830 A1
(43) Pub. Date: Mar. 6, 2025

(54) REMOTE COMPUTER ACCESS LOCKOUT SYSTEMS AND METHODS FOR SUBSTRATE PROCESSING SYSTEMS

(71) Applicant: ASM IP Holding B.V., Almere (NL)

(72) Inventors: Eric Steinseifer, Tempe, AZ (US); Quan Zhang, Mesa, AZ (US)

(21) Appl. No.: 18/815,589

(22) Filed: Aug. 26, 2024

Related U.S. Application Data
(60) Provisional application No. 63/535,914, filed on Aug. 31, 2023.

(51) Int. Cl. G05B 15/02; H01H 27/08; H01L 21/67

(52) U.S. Cl. CPC G05B 15/02; H01H 27/08; H01L 21/67167

(57) ABSTRACT

Substrate processing systems and methods include selectively activatable remote computer access having lockout and/or tagout controls and/or features. Such substrate processing systems may include: (a) a first network switch including an input port and an output port; (b) a second network switch including an input/output port directly or indirectly connected with the first switch output port; (c) a lockable key switch provided in a power supply line and movable between OFF and ON positions; and (d) a key for moving the key switch between ON and OFF. When ON, an electrical circuit for supplying power to the first network switch and/or second network switch is completed, enabling remote computer control of the substrate processing system. When OFF, an electrical circuit for supplying power to the first network switch and/or second network switch is interrupted, thereby disabling remote computer control. The key can only be removed when in the OFF position.

### CROSS-REFERENCE TO RELATED APPLICATION(S)

This application claims the benefit of U.S. Provisional Application 63/535,914 filed on Aug. 31, 2023, the entire contents of which are incorporated herein by reference.

### FIELD OF THE DISCLOSURE

The present disclosure relates generally to systems and methods for controlling remote access to substrate processing systems. Some more particular aspects of this technology relate to substrate processing systems and methods in which incoming remote computer signals may be enabled and disabled. Some aspects of this technology relate to substrate processing systems and methods in which incoming remote computer signals may be enabled and disabled using lockout and/or tagout (e.g., “LOTO”) controls and/or features.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Existing substrate processing systems include “cluster type” systems in which a single substrate handling chamber is operatively connected with two to four substrate processing chambers via gate valves. Each substrate processing chamber is equipped to receive a substrate on a substrate support that holds the substrate during processing (e.g., during material layer deposition as described above). The substrate handling chamber includes a robotic arm used to move substrates into and out of the various substrate processing chambers through the gate valves.

Substrate processing systems of this type often have remote access and remote operation capabilities allowing the system to be controlled, at least in part, by a party located remote from the substrate processing system location. Such remote access and operation capabilities, however, can increase the potential for safety hazards. For example, at some times, one or more of the substrate handling chamber, substrate processing chambers, and/or other equipment may not be powered down during service or repair, e.g., when service or repairs are conducted on other components. At such times, a technician may require access to the interior chamber of one or more of the substrate handling chamber, substrate processing chambers, and/or other equipment to complete the necessary work. Remote activation of some portion of the substrate processing system while a repair or service is taking place, e.g., by a remotely located party, risks injury to anyone involved with the repair or service.

At some times, service technicians may need to calibrate sensors, e.g., sensors associated with one or more robotic arms (e.g., automatic wafer centering (or “AWC”) sensors included with robots used in substrate handling chambers). If a remote operator activates the robotic arm before the calibration is finished and the data is saved, unsaved data will be lost. This results in the need to begin calibration anew (at least from the last saved point), which increases costs and wastes service technician time.

In an effort to avoid issues of these types, during repairs or service, a technician may prevent undesired remote activation of the substrate processing system, e.g., by physically disconnecting the remote computer's Ethernet connection from the input port of the substrate processing system's processing computer. While generally acceptable and effective for the intended purpose at preventing undesired startup of the substrate processing system by a remote user via the Ethernet connection, this arrangement has some drawbacks. For example, when finished, the technician may forget to reconnect the Ethernet cable and/or reconnect the cable to an incorrect port, e.g., resulting in longer system “down time” than intended and/or necessary. Additionally or alternatively, a “passerby” may notice the unplugged cable and plug it back in while the repair or service continues. Thus, there is room for improvement in remote control and access to such substrate processing systems.

### SUMMARY OF THE DISCLOSURE

Aspects of this technology relate to systems and methods for controlling remote access to substrate processing systems. Some more particular aspects of this technology relate to substrate processing systems and methods in which incoming remote computer control signals may be enabled and disabled. Additionally or alternatively, some aspects of this technology relate to substrate processing systems and methods in which incoming remote computer control signals (for controlling any portion of a substrate processing system) may be enabled and disabled using lockout and/or tagout controls and/or features. The lockout controls and/or features may include a locking system movable between an “enable” or “ON” position and a “disable” or “OFF” position to allow: (a) control of the power supply to one or more components within a remote data transmission system or method and/or (b) control of one or more data transmission lines or systems within a remote data transmission system or method.

Substrate processing systems in accordance with at least some examples of this technology include one or more of: (a) a first switch including a first input port, a first power input, and a first output port; (b) a second switch including a first input/output port and a second power input; (c) a first electrical connector electrically connecting the first power input and the second power input; (d) a lockable key switch provided in the first electrical connector, the lockable key switch being movable between an off position and an on position; (c) a power source connected to the first electrical connector; and/or (f) a key configured to be received by the lockable key switch and configured to move the lockable key switch between the on position and the off position when received by the lockable key switch. In the on position, the power source supplies power to the first switch and the second switch. In the off position, no power is supplied at least to the first switch.

In addition to one or more of the features described above, or as an alternative, in at least some examples of this technology, the key will be removable from the lockable key switch only when the lockable key switch is in the off position.

In addition to one or more of the features described above, or as an alternative, in at least some examples of this technology, the first input port will be configured to receive substrate processing commands from a remote computing system, and/or the first output port will be connected (directly or indirectly) to the first input/output port of the second switch to transmit the substrate processing commands from the remote computing system, through the first switch, and to the second switch only when the lockable key switch is in the on position.

In addition to one or more of the features described above, or as an alternative, substrate processing systems in accordance with some examples of this technology may further comprise one or more substrate processing chambers in electronic communication with the second switch, wherein at least one of the one or more substrate processing chambers receives input data transmitted through the second switch based on the substrate processing commands received from the remote computing system only when the lockable key switch is in the on position.

In addition to one or more of the features described above, or as an alternative, substrate processing systems in accordance with some examples of this technology may further comprise a substrate processing system host computer, wherein the first input port is configured to receive substrate processing commands from a remote computing system, wherein the first output port is connected to the substrate processing system host computer and transmits the substrate processing commands from the remote computing system, through the first switch, and to the substrate processing system host computer only when the lockable key switch is in the on position, and wherein the substrate processing system host computer transmits signals to the first input/output port of the second switch based on the substrate processing commands received from the remote computing system.

In addition to one or more of the features described above, or as an alternative, substrate processing systems in accordance with some examples of this technology may further comprise one or more substrate processing chambers in electronic communication with the second switch, wherein at least one of the one or more substrate processing chambers receives input data transmitted through the second switch based on the substrate processing commands received from the remote computing system only when the lockable key switch is in the on position.

In addition to one or more of the features described above, or as an alternative, in at least some examples of this technology, the first input port comprises an ethernet port.

In addition to one or more of the features described above, or as an alternative, in at least some examples of this technology, the power source is a DC power source.

Substrate processing systems in accordance with at least some examples of this technology include one or more of: (a) a first switch including a first input port, a first power input, and a first output port; (b) a second switch including a first input/output port and a second power input, wherein the first output port is directly or indirectly connected with the first input/output port of the second switch; (c) a lockable key switch movable between an off position and an on position, the lockable key switch being provided in a power supply line connected to supply power to at least one of the first power input or the second power input; and/or (d) a key configured to be received by the lockable key switch. This key is configured to move the lockable key switch between the on position and the off position when received by the lockable key switch. In the on position, an electrical circuit including the power supply line for supplying power to at least one of the first power input or the second power input is completed. In the off position, an electrical circuit including the power supply line for supplying power to at least one of the first power input or the second power input is interrupted.

In addition to one or more of the features described above, or as an alternative, in at least some examples of this technology, the key will be removable from the lockable key switch only when the lockable key switch is in the off position.

In addition to one or more of the features described above, or as an alternative, in at least some examples of this technology, the first input port will be configured to receive substrate processing commands from a remote computing system, and/or the first output port will be directly connected to the first input/output port of the second switch to transmit the substrate processing commands from the remote computing system, through the first switch, and to the second switch only when the lockable key switch is in the on position.

In addition to one or more of the features described above, or as an alternative, substrate processing systems in accordance with some examples of this technology may further comprise one or more substrate processing chambers in electronic communication with the second switch, wherein at least one of the one or more substrate processing chambers receives input data transmitted through the second switch based on the substrate processing commands received from the remote computing system only when the lockable key switch is in the on position.

In addition to one or more of the features described above, or as an alternative, substrate processing systems in accordance with some examples of this technology may further comprise a substrate processing system host computer, wherein the first input port is configured to receive substrate processing commands from a remote computing system, wherein the first output port is connected to an input of the substrate processing system host computer and transmits the substrate processing commands from the remote computing system, through the first switch, and to the substrate processing system host computer only when the lockable key switch is in the on position, and wherein the substrate processing system host computer transmits signals to the first input/output port of the second switch based on the substrate processing commands received from the remote computing system.

In addition to one or more of the features described above, or as an alternative, substrate processing systems in accordance with some examples of this technology may further comprise one or more substrate processing chambers in electronic communication with the second switch, wherein at least one of the one or more substrate processing chambers receive input data transmitted through the second switch based on the substrate processing commands received from the remote computing system only when the lockable key switch is in the on position.

Methods of connecting a substrate processing system with a remote computing system in accordance with at least some examples of this technology may comprise one or more of: (a) connecting a remote computing system with a first input port of a first switch, the first switch further including a first power input and a first output port; (b) directly or indirectly connecting the first output port of the first switch with a first input/output port of a second switch, the second switch further including a second power input; (c) electrically connecting the first power input and the second power input with an electrical connector that includes a lockable key switch, the lockable key switch being movable using a key between an off position and an on position; and/or (d) connecting a power source with the electrical connector. The lockable key switch is provided in the electrical connector such that: (i) when the lockable key switch is in the on position, the power source supplies power to the first switch and the second switch, and (ii) when the lockable key switch is in the off position, no power is supplied to at least one of the first switch or the second switch by the power source.

In addition to one or more of the features described above, or as an alternative, methods in accordance with some examples of this technology may further comprise disabling operation of the substrate processing system by turning the lockable key switch from the on position to the off position using the key; and/or removing the key from the lockable key switch.

In addition to one or more of the features described above, or as an alternative, methods in accordance with some examples of this technology may further comprise enabling operation of the substrate processing system by engaging the key with the lockable key switch while the lockable key switch is in the off position; and/or turning the lockable key switch from the off position to the on position using the key.

Methods of connecting a substrate processing system with a remote computing system in accordance with at least some examples of this technology may comprise one or more of: (a) connecting a remote computing system with a first input port of a first switch, the first switch further including a first power input and a first output port; (b) directly or indirectly connecting the first output port of the first switch with a first input/output port of a second switch, the second switch further including a second power input; (c) electrically connecting at least one of the first power input or the second power input with an electrical connector that includes a lockable key switch, the lockable key switch being movable using a key between an off position and an on position; and/or (d) connecting a power source with the electrical connector. The lockable key switch is provided in the electrical connector such that: (i) when the lockable key switch is in the on position, the power source supplies power to at least one of the first switch or the second switch, and (ii) when the lockable key switch is in the off position, no power is supplied to at least one of the first switch or the second switch by the power source.

In addition to one or more of the features described above, or as an alternative, methods in accordance with some examples of this technology may further comprise disabling operation of the substrate processing system by turning the lockable key switch from the on position to the off position using the key; and/or removing the key from the lockable key switch.

In addition to one or more of the features described above, or as an alternative, methods in accordance with some examples of this technology may further comprise enabling operation of the substrate processing system by engaging the key with the lockable key switch while the lockable key switch is in the off position; and/or turning the lockable key switch from the off position to the on position using the key.

This Summary is provided to introduce a selection of concepts relating to this technology in a simplified form. These concepts are described in further detail in the Detailed Description below. This Summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 schematically illustrates an overhead view of a “cluster type” substrate processing system in accordance with some examples of this technology;

FIG. 2 schematically illustrates connection of a substrate processing system with a remote computer system in accordance with some examples of this technology;

FIG. 3 illustrates example features of a control panel with lockout capability for enabling and disabling remote computer operation of substrate processing systems and methods in accordance with some examples of this technology;

FIG. 4 schematically illustrates an overhead view of another “cluster type” substrate processing system in accordance with some examples of this technology;

FIG. 5 schematically illustrates another connection of a substrate processing system with a remote computer system in accordance with some examples of this technology; and

FIG. 6 illustrates method features and aspects for remote access in substrate processing systems and methods in accordance with some examples of this technology.

It will be appreciated that elements in the figures are illustrated for simplicity and clarity and have not necessarily been drawn to scale and/or with full detail. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

The terms “input port” and “output port” when used herein to denote ports for receiving and/or transmitting data include within their scope data and/or communication ports used for both receiving input and transmitting output (e.g., “input/output ports”). Thus, while the term “input port” may be used herein to describe a specific part of a component, the hardware providing that “port” may actually be configured to and capable of receiving input from one or more other components and transmitting output to one or more other components. Similarly, while the term “output port” may be used herein to describe a specific part of a component, the hardware providing that “port” may actually be configured to and capable of receiving input from one or more other components and transmitting output to one or more other components.

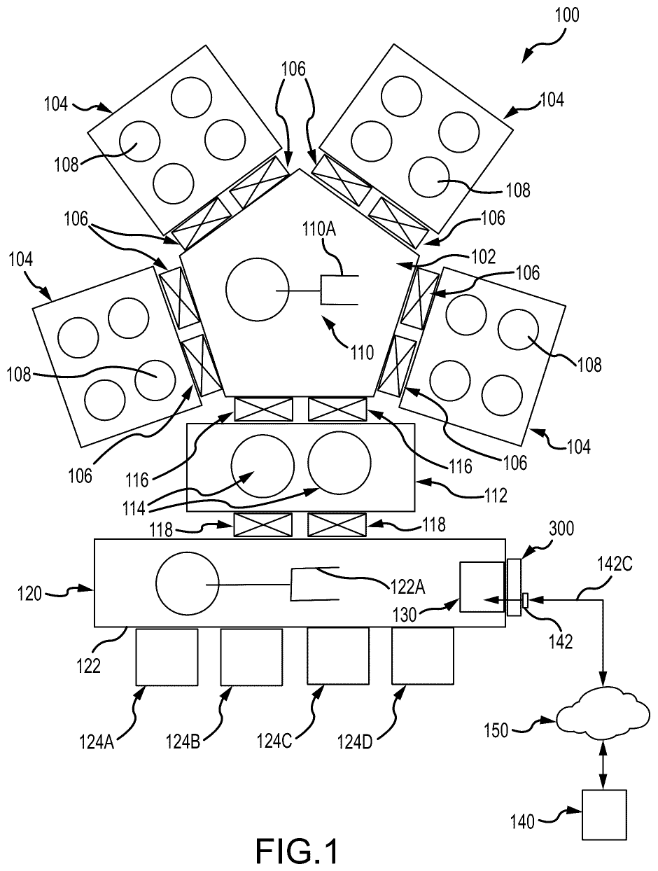

As noted above, material layers are commonly deposited onto substrates during fabrication of semiconductor devices, such as during fabrication of integrated circuits and electronic devices. FIG. 1 illustrates a “cluster type” substrate processing system 100 in accordance with some examples of this technology. This example substrate processing system 100 includes a substrate handling chamber 102 that operatively connects with one to four substrate processing chambers 104 via gate valves 106. Each substrate processing chamber 104 includes one or more substrate supports and is equipped to receive a substrate on the substrate support 108 and hold the substrate during processing (e.g., during material layer deposition as described above, during etching processes, etc.). FIG. 1 shows each substrate processing chamber 104 including four substrate supports 108 onto which substrates can be placed during processing. More or fewer substrates supports 108 may be provided in each substrate processing chamber 104 (e.g., the substrate processing chambers 104 may be dual chamber modules (DCM) or quad chamber modules (QCM)). Substrate processing chambers 104 in accordance with some examples of this technology may include another four substrate supports 108 located vertically beneath the four substrate supports 108 shown in the top view of FIG. 1. Each of the substrate processing chambers 104 may have the same structures or one or more of the substrate processing chambers 104 may have a different structure from other substrate processing chambers 104 present.

The substrate handling chamber 102 includes robotic arm 110 used to move substrates into and out of the various substrate processing chambers 104 through the gate valves 106. In use, a gate valve 106 is opened, an end effector 110A of the robotic arm 110 extends through the open gate valve 106 to insert a substrate into or remove a substrate from an interior chamber of the substrate processing chamber 104 (e.g., placing a substrate on or taking a substrate off a substrate support 108 within the substrate processing chamber 104). Once the robotic arm 110 is retracted from the substrate processing chamber 104, the gate valve 106 is closed, thereby sealing the substrate processing chamber 104 from the substrate handling chamber 102. Then, other desired actions can take place in the substrate processing chamber 104 (e.g., material layer deposition, etching, etc.) and/or the substrate handling chamber 102.

FIG. 1 further shows that this example substrate processing system 100 includes a load-lock module 112. The load-lock module 112 is connected with the substrate handling chamber 102 by one or more gate valves 116. The load-lock module 112 includes substrate holding components 114 for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition, etching, and/or other processing) and from the substrate handling chamber 102 into the load-lock module 112 (after processing is completed). The load-lock module 112 and gate valve(s) 116 keep the substrates isolated from the environment of the substrate handling chamber 102 until the conditions (e.g., temperature, pressure, content of atmosphere, etc.) within the substrate handling chamber 102 are ready for the substrate(s) to be inserted, e.g., while waiting for all gate valves 106 to be closed.

The load-lock module 112 further is coupled with an equipment front end module 120 via one or more additional gate valves 118. The equipment front end module 120 includes a robotic arm 122. The end effector 122A of that robotic arm 122 moves through the gate valve(s) 118 (when opened) to move substrates from the equipment front end module 120 into the load-lock module 112 (for layer deposition, etching, and/or other processing) and from the load-lock module 112 into the equipment front end module 120 (after processing is completed). The robotic arm 122 of the equipment front end module 120 also picks up new substrates for processing from one of the load ports 124A-124D and returns processed substrates to one of the load ports 124A-124D, e.g., to be transported to another location for further processing or other action.

FIG. 1 further shows a universal processing computer 130 (also called a “substrate processing system host computer” herein). Universal processing computer 130 may be used to control and coordinate operation (e.g., “scheduling” the various functions and operations) of the substrate handling chamber 102, the substrate processing chambers 104, the load-lock module 112, the equipment front end module 120, the load ports 124A-124D, the robotic arms 110, 122, the gate valves 106, 116, 118, and any equipment included within any of these components. The universal processing computer 130 also may have data logging functions (e.g., performing equipment data acquisition (“EDA”) functions). While FIG. 1 shows universal processing computer 130 housed with the equipment front end module 120, it could be provided as part of any of the other component parts (e.g., the substrate handling chamber 102, one or more of the substrate processing chambers 104, the load-lock module 112, etc.) and/or it could be provided as a separate standalone component or at a separate workstation. FIG. 1 further shows a remote computer 140 connected with the universal processing computer 130 via an input port 142, which may comprise, at least in part, an Ethernet port and an Ethernet cable 142C connection, although any other desired type of wired and/or wireless connections and/or communications may be used in other examples of this technology. Remote computer 140 may be provided at any desired location and may be connected with substrate processing system 100 via the Internet and/or other desired network connection (represented by the “cloud” 150 in FIG. 1). While FIG. 1 shows the input port 142 provided at a control panel 300 (example features of which are described in more detail below), input port 142 may be directly connected with the universal processing computer 130 and/or otherwise connected to communicate with and to provide data for operating the substrate processing system 100. While FIG. 1 shows the control panel 300 provided on the equipment front end module 120, the control panel 300 location may vary in other specific examples of this technology, including on the load-lock module 112, on one of the substrate processing chambers 104, at a standalone or separate work station, and/or at another desired location.

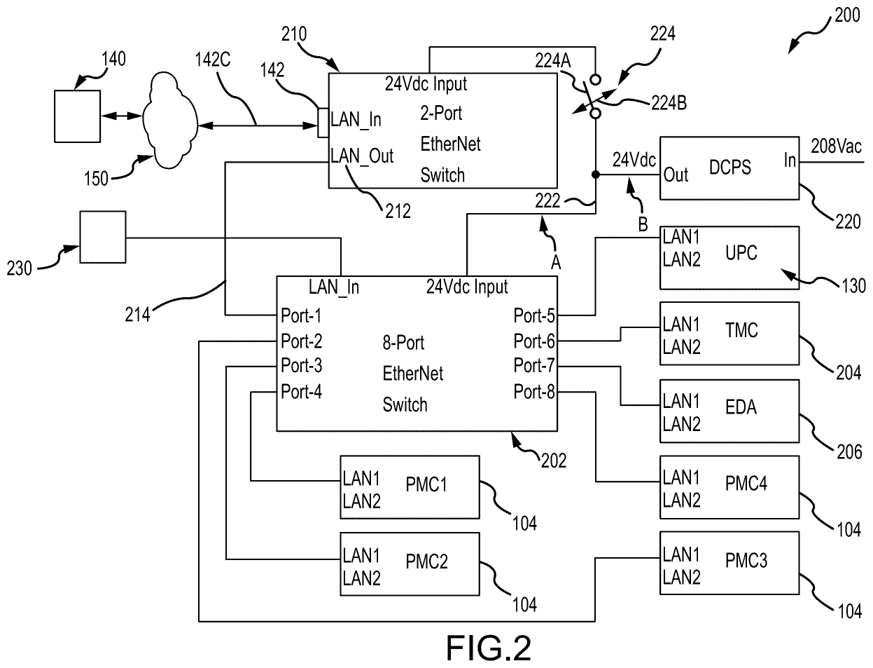

At least some aspects of this technology relate to the manner in which a remote computer 140 is connected with a substrate processing system 100 and/or the manner in which this connection operates, e.g., to provide data and information to the universal processing computer 130 for remotely controlling and operating the substrate processing system 100. FIG. 2 schematically illustrates at least a portion of a connection system 200 in accordance with one example of this technology. As shown in FIG. 2, the connection system 200 includes a network switching system 202 (e.g., an 8-port Ethernet switch in this example). One input/output port (labeled “Port-5” in FIG. 2) of the network switching system 202 is connected with the universal processing computer 130. Four of the other input/output ports of the network switching system 202 (labeled Port-2, Port-3, Port-4, and Port-8 in FIG. 2) are connected with the various substrate processing chambers 104 to transmit data between the universal processing computer 130 and the substrate processing chambers 104 (e.g., signals to control the heaters, pumps, gate valves, processing conditions, etc.). Other input/output ports are provided in communication with transfer module computer 204 (via Port-6), e.g., for controlling transfer of substrates through the various components of substrate processing system 100, including scheduling of movements of substrates, and an equipment data acquisition (“EDA”) computer system 206 (via Port-7), e.g., a software tool that assists in data logging. The local area network input port of network switching system 202 of this illustrated example is connected to a host computer 230, e.g., controlled by the manufacturer of the facility where the substrate processing system 100 is located.

The connection system 200 of FIG. 2 further includes another network switching system 210, which comprises a two-port Ethernet port in this specifically illustrated example. This additional network switching system 210 includes input port 142 discussed above, which receives incoming data (e.g., substrate processing commands to be carried out in one or more of the substrate processing chambers 104 and/or other commands for controlling some portion of the substrate processing system 100) from the remote computer 140 over a network connection. The output port 212 of network switching system 210 is connected with an input/output port (“Port-1”) of network switching system 202 (e.g., via communication line 214), e.g., to transmit data from the remote computer 140 to network switching system 202 (which may, in turn, transmit the data to the universal processing computer 130 via network switching system 202). Alternatively, if desired, remote computer 140 data may be transmitted from the output port 212 to another input location, such as an input port provided directly on the universal processing computer 130. Network switching system 210 also is referred to as a “first switch” or “first switching system” herein, and switching system 202 also is referred to as a “second switch” or “second switching system” herein.

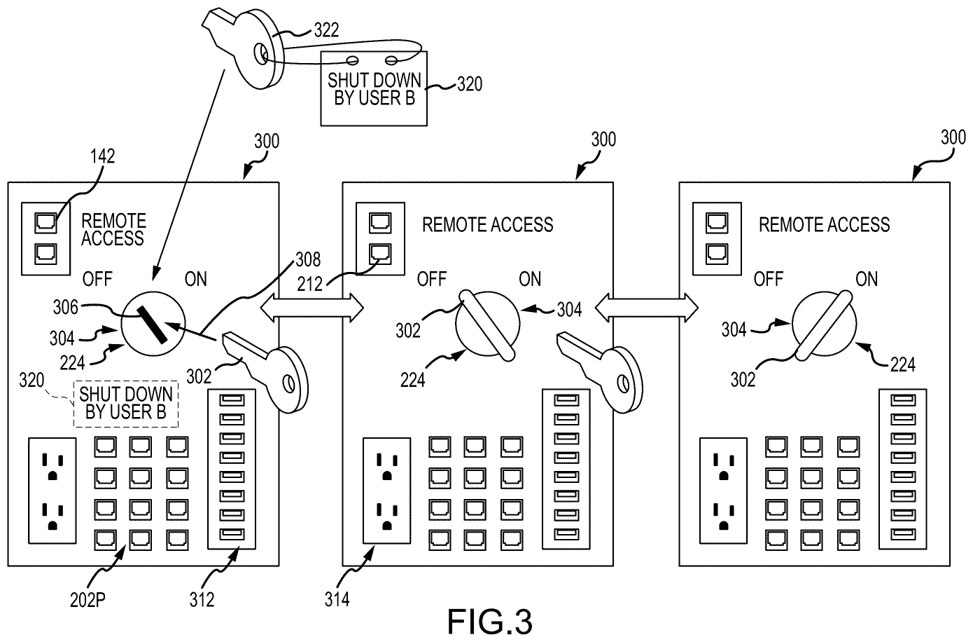

Power control features of the connection system 200 now will be described in conjunction with FIGS. 2 and 3. As shown in FIG. 2, connection system 200 of this example further includes a DC power source 220 for supplying power to each of network switching system 202 and network switching system 210 via power line 222. Power line 222 of this example comprises an electrical connector electrically connecting with a power input of network switching system 202 (e.g., a 24 volt DC power input port) and with the power input of network switching system 210 (e.g., a 24 volt DC power input port). Power line 222 of this example further includes a key switch 224. Key switch 224 turns at least network switching system 210 ON and OFF. When the key switch 224 is closed (“ON”), power from the power source 220 makes network switching system 210 operable so that data can move from the remote computer 140, through the network switching system 210, through output port 212, into network switching system 202 (or otherwise routed) to the universal processing computer 130. When the key switch 224 is open (“OFF”), no power from the power source 220 reaches network switching system 210 so that network switching system 210 is inoperable and does not move data from the remote computer 140 through the network switching system 210. In this manner, key switch 224 can be used to control whether remote computer 140 is capable of operating the substrate processing system 100.

FIG. 3 illustrates a portion of a control panel 300 including a portion of the key switch 224 with which a user may interact. As shown at the left side of FIG. 3, the key 302 may be inserted into a key slot 306 of locking system 304. See arrow 308. In this example locking system 304, the key 302 can only be inserted into the key slot 306 and removed from the key slot 306 when the locking system 304 is in the OFF position. Once the key 302 is inserted into the key slot 306 (e.g., as shown in the center of FIG. 3), the key 302 then can be turned to the ON position (which activates the network switching system 210 and enables remote computer 140 access and control of substrate processing system 100). See the right side of FIG. 3. Turning the locking system 304 with the key 302 may physically move switch member 224A (see arrow 224B in FIG. 2) between the open or OFF position (as shown in FIG. 2 and the middle of FIG. 3) and the closed or ON position (as shown at the right side of FIG. 3). When OFF, movable switch member 224A opens the circuit of power line 222 so that no power reaches the network switching system 210 (i.e., network switching system 210 is in an “unpowered” condition). This disables remote computer 140 access and control of substrate processing system 100. When “ON,” movable switch member 224A closes the circuit of power line 222 and supplies power to operate the network switching system 210.

Locking system 304 shown in FIG. 3 may include or connect directly with movable switch member 224A shown in FIG. 2 to physically and directly move switch member 224A between the open and closed positions. Alternatively, if desired, some mechanical connectors and/or linkage may be provided to physically move switch member 224A in response to movement of locking system 304 with the key. Other types of physical arrangements, linkages, connections, and/or components (including electronic, wired, and/or wireless connections) may be used to change key switch 224 between the open and closed positions in response to the locking system 304 moving between its ON and OFF positions.

As shown and described above in conjunction with FIG. 3, key switch 224 and locking system 304 may have various features or characteristics. For example, the key switch 224 may be lockable, e.g., with the key 302 engaging the locking system 304. Additionally, the key 302 may be removable from the locking system 304 only when the key switch 224 and locking system 304 are in the OFF position. Additionally, with the key switch 224 and the locking system 304 in the OFF position, the network switching system 210 will be in an “unpowered” condition. Thus, if a user turns the locking system 304 to the OFF position and removes the key 302, the network switching system 210 cannot receive power—and thus the remote computer 140 cannot control the substrate processing system 100—unless and until a suitable key 302 is used to move the locking system 304 to the ON position. Thus, the substrate processing chamber(s) 104 and/or other components of the substrate processing system 100 can receive commands from the remote computer 140 only when the lockable key switch 224 is in the ON position. In this manner, a technician can disable remote access (by turning the locking system 304 to the OFF position and removing the key 302), and they can then perform repairs or service on some portion of the substrate processing system 100 with less concern that the substrate processing system 100 might be activated by a remote computer 140.

While not a requirement in all examples of this technology, FIG. 3 further illustrates that control panel 300 may have additional features. As some more specific examples, control panel 300 may include the input port 142 (e.g., an Ethernet port) for the remote computer 140 on network switching system 210; the output port 212 from network switching system 210; one or more ports 202P for network switching system 202; one or more USB or other input ports (e.g., ports 312); and/or one or more power outlets 314. While not illustrated in FIG. 3, a control panel also may include one or more interfaces for user input devices, such as a touch screen, a computer pointing device (such as a mouse, joystick, eraser head, etc.), a keyboard (hard or soft), etc.

In at least some examples in this technology, the overall locking system 304 may include some manner of advising other users as to who has locked the locking system 304 when the key 302 is removed. As some more specific examples, when the key 302 is removed, the party removing the key 302 may (and may be required to) place a removable “tag” 320 of some sort on or near the substrate processing system 100. Additionally or alternatively, the tag 320 may be provided on the control panel 300 (e.g., clipped on, attached by magnet, attached by a hook-and-loop fastener, snapped on, stuck on, etc.); in the key slot 306 (e.g., an “inoperative” key 322 that can fit in key slot 306, does not move the switch member 224A of key switch 224, and includes the user's identification information on a tag 320); on a board or sheet located near the substrate processing system 100; etc. In this manner, the lockable key switch 224 and locking system 304 may have and/or provide “lock out/tag out” or “LOTO” features. Additionally or alternatively, other types of “lock out/tag out” or “LOTO” features, systems, and/or components may be provided for locking systems 304 for use on other specific examples of this technology (such as a lock component used to physically lock the locking system 304 in the OFF position).

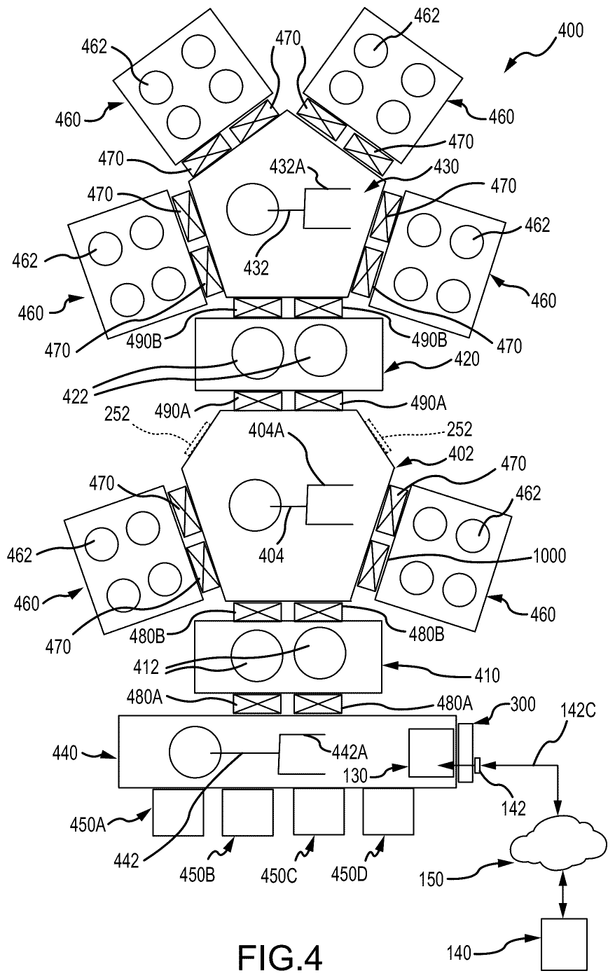

FIG. 4 schematically illustrates an overhead view of another example substrate processing system 400 in accordance with some examples of this technology (another “cluster” type semiconductor processing system). This substrate processing system 400 may be of the type described in U.S. Provisional Patent Appln. No. 63/524,272 filed Jun. 30, 2023 and entitled “Extended Substrate Processing Systems and Methods with Additional Processing Chamber Connectability.” U.S. Provisional Patent Appln. No. 63/524,272 is entirely incorporated herein by reference.

The substrate processing system 400 shown in FIG. 4 includes: (a) a first substrate handling chamber 402 (an “inboard” substrate handling chamber) including a first robotic arm 404 having an end effector 404A; (b) a first load-lock module 410 (an “inboard” load-lock module) connected at one edge or facet of the first substrate handling chamber 402; (c) a second load-lock module 420 (an “outboard” load-lock module) connected at the opposite edge or facet of the first substrate handling chamber 402; and (d) a second substrate handling chamber 430 (an “outboard” substrate handling chamber) including a second robotic arm 432 having an end effector 432A. The second load-lock module 420 extends between and connects the first substrate handling chamber 402 and the second substrate handling chamber 430. The first load-lock module 410 of this example also is connected with an equipment front end module 440 that includes a third robotic arm 442 having an end effector 442A. The equipment front end module 440 may include or connect with a nitrogen gas source for providing a nitrogen gas atmosphere within the equipment front end module 440. The equipment front end module 440 receives new substrates for processing into the substrate processing system 400 and discharges processed substrates from the substrate processing system 400 via one or more loading ports 450A-450D (moving the substrates between the loading port(s) 450A-450D and the first load-lock module 410 using the robotic arm 442). While four loading ports 450A-450D are shown in the example of FIG. 4, more or fewer loading ports may be provided in other examples of this technology.

Each of the first substrate handling chamber 402 and the second substrate handling chamber 430 is connected with (or connectable to) multiple substrate processing chambers 460. Substrates are transferred into the substrate processing chambers 460 where one or more layers of material are deposited onto a surface of the substrate and/or other desired substrate processing takes place. FIG. 4 shows each substrate processing chamber 460 including four substrate supports 462 onto which substrates can be placed during processing. More or fewer substrates supports 462 may be provided in each substrate processing chamber 460 (e.g., the substrate processing chambers 460 may be dual chamber modules (DCM) or quad chamber modules (QCM)). Substrate processing chambers 460 in accordance with some examples of this technology may include another four substrate supports 462 located vertically beneath the four substrate supports 462 shown in the top view of FIG. 4. Each of the substrate processing chambers 460 may have the same structures or one or more of the substrate processing chambers 460 may have a different structure from other substrate processing chambers 460 present.

Each of the first substrate handling chamber 402 and the second substrate handling chamber 430 is connected with its respective substrate processing chambers 460 via one or more gate valves 470. While two gate valves 470 are shown connecting substrate handling chambers 402, 430 with each of their respective substrate processing chambers 460, more or fewer gate valves 470 may be provided with each substrate processing chamber 460, in other examples of this technology. Substrate processing chambers 460 in accordance with some examples of this technology may be connected with their respective substrate handling chamber 402, 430 by another two gate valves 470, e.g., located vertically beneath the two gate valves 470 shown in the top view of FIG. 4. When closed, the gate valves 470 sealingly separate the substrate handling chambers 402, 430 from their respective substrate processing chambers 460 (so that independent atmospheric conditions may be maintained in each chamber). When open, the gate valves 470 provide an opening (e.g., a substrate transfer slot) through which the end effector 404A, 432A of a robotic arm 404, 432 can extend to move substrates into and out of the substrate processing chamber 460. The openings through the gate valves 470 align with substrate transfer slots provided in the substrate processing chambers 460 and the substrate handling chambers 402, 430, to enable substrates to be moved between the substrate processing chambers 460 and the substrate handling chambers 402, 430 through the gate valves 470. Each of gate valves 470 may have the same structures or one or more of the gate valves 470 may have a different structure from other gate valves 470 present.

One face of the first load-lock module 410 connects with the equipment front end module 440 by one or more gate valves 480A (two shown in FIG. 4), and the opposite face of the first load-lock module 410 connects with the first substrate handling chamber 402 by one or more gate valves 480B (two shown in FIG. 4). The first load-lock module 410 further includes one or more substrate supports 412 (two shown in FIG. 4) for holding substrates while they wait to be moved into the equipment front end module 440 or the first substrate handling chamber 402. When closed, the gate valves 480A, 480B sealingly separate the load-lock module 410 from the equipment front end module 440 and the substrate handling chamber 402 (so that independent atmospheric conditions may be maintained in each chamber). When open, the gate valves 480A provide an opening (e.g., a substrate transfer slot) through which the end effector 442A of robotic arm 442 can extend to move substrates into and out of the equipment front end module 440. The openings through the gate valves 480A align with substrate transfer slots provided in the equipment front end module 440 and the first load-lock module 410 to enable substrates to be moved between the equipment front end module 440 and the first load-lock module 410 through gate valves 480A. When open, the gate valves 480B provide an opening (e.g., a substrate transfer slot) through which the end effector 404A of robotic arm 404 can extend to move substrates into and out of the substrate handling chamber 402. The openings through the gate valves 480B align with substrate transfer slots provided in the substrate handling chamber 402 and the first load-lock module 410 to enable substrates to be moved between the substrate handling chamber 402 and the first load-lock module 410 through gate valves 480B. Each of gate valves 480A, 480B may have the same structure or one or more of the gate valves 480A, 480B may have a different structure from other gate valves 470, 480A, 480B present.

In the substrate processing system 400 of FIG. 4, one face of the second load-lock module 420 connects with the first substrate handling chamber 402 by one or more gate valves 490A (two shown in FIG. 4), and the opposite face of the second load-lock module 420 connects with the second substrate handling chamber 430 by one or more gate valves 490B (two shown in FIG. 4). The second load-lock module 420 further includes one or more substrate supports 422 (two shown in FIG. 2) for holding substrates while they wait to be moved between the two substrate handling chambers 402, 430. When closed, the gate valves 490A, 490B sealingly separate the second load-lock module 420 from the two substrate handling chambers 402, 430 (so that independent atmospheric conditions may be maintained in each chamber). When open, the gate valves 490A provide an opening (e.g., a substrate transfer slot) through which the end effector 404A of robotic arm 404 can extend to move substrates into and out of the first substrate handling chamber 402. The openings through the gate valves 490A align with substrate transfer slots provided in the first substrate handling chamber 402 and the second load-lock module 420 to enable substrates to be moved between the substrate handling chamber 402 and the second load-lock module 420 through gate valves 490A. When open, the gate valves 490B provide an opening (e.g., a substrate transfer slot) through which the end effector 432A of robotic arm 432 can extend to move substrates into and out of the second substrate handling chamber 430. The openings through the gate valves 490B align with substrate transfer slots provided in the second substrate handling chamber 430 and the second load-lock module 420 to enable substrates to be moved between the second substrate handling chamber 430 and the second load-lock module 420 through gate valves 490B. Each of gate valves 490A, 490B may have the same structure or one or more of the gate valves 490A, 490B may have a different structure from other gate valves 490A, 490B present. Gate valves 490A and/or 490B also may have the same or different structures from gate valves 470, 480A, and/or 480B.

The first load-lock module 410 may have the same structure as the second load-lock module 420 and/or the first and second load-lock modules 410, 420 may be interchangeable (e.g., so that load-lock modules 410, 420 can switch positions and/or have a modular structure). In other examples, the first load-lock module 410 and the second load-lock module 420 may have different structures and/or may not be interchangeable (e.g., so that load-lock modules 410, 420 cannot switch positions in the substrate processing system 400). Either or both load-lock modules 410, 420 may be multi-station cooling capable and/or path through types.

As shown in broken lines in FIG. 4, two smaller facets of the first substrate handling chamber 402 may be equipped with at least one substrate transfer slot 252. The substrate transfer slot(s) 252, when present, may be sealed (e.g., by a removable seal plate) in substrate processing system 400 arrangements of the type shown in FIG. 4 where no substrate processing chamber 460 is attached to those facets. The substrate transfer slot(s) 252 in these facets also may be smaller than corresponding slots in the other facets of the first substrate handling chamber 402 and/or the second substrate handling chamber 430 (although transfer slot(s) 252 need not be smaller in all examples of this technology). Thus, these smaller facets may be connected to substrate processing chambers via additional gate valves, if desired (optionally, smaller substrate processing chambers).

FIG. 4 further shows that this example substrate processing system 400 includes a universal processing computer 130 connected with a remote computer 140 via an appropriate communication connection (e.g., a connecting cable 142C, an input port 142, and a network connection) and a control panel 300. These parts in the substrate processing system 400 of FIG. 4 may have any of the structures, functions, options, and/or alternatives described for these parts above in conjunction with FIGS. 1-3. In some examples of this technology, the substrate processing system 400 of FIG. 4 also may include a remote computer 140 connection system 200 of the type described above in conjunction with FIGS. 1-3.

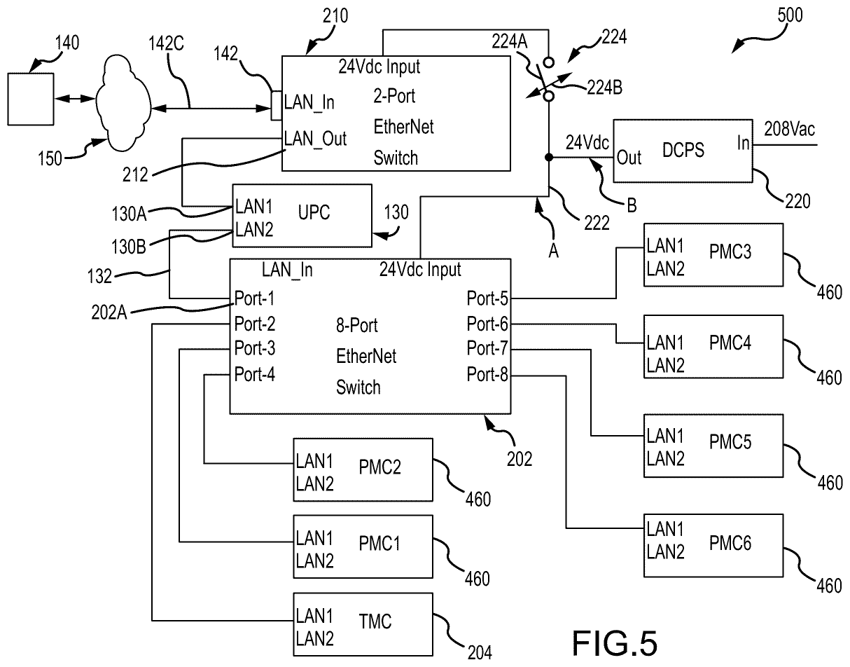

In other examples of this technology, the substrate processing system 400 of FIG. 4 may include a different type of remote computer 140 connection system, such as the connection system 500 shown in FIG. 5. Where the same reference numbers are used in FIG. 5 as used in any of FIGS. 1-4, the same or similar parts are being referenced (with any of the options, alternatives, or features for that part described above), and much of the overlapping description may be omitted. The discussion below will focus primarily on differences between the connection system 500 of FIG. 5 and the connection system 200 discussed above. The connection system 500 of FIG. 5 also could be used in the substrate processing system 100 of FIG. 1, in at least some examples of this technology.

As shown in FIG. 5, the network switching system 202 of this example (e.g., an 8-port Ethernet switch) has six of its ports (labelled Port-3 through Port-8) connected to provide data and communications with the six substrate processing chambers 460 shown in FIG. 4. Further, an input/output port is provided in communication with transfer module computer 204 (via Port-2), e.g., for controlling transfer of substrates through the various components of substrate processing system 400. Any type of connections can be provided, such as connections using Ethernet cables extending between the network switching system 202 and input/output ports of the substrate processing chambers 460 and/or transfer module computer 204. The connection system 500 of FIG. 5 further includes the DC power source 220 connected with the DC input ports of network switching system 202 and network switching system 210, e.g., via power line 222 in the same manner discussed above for the systems of FIGS. 1-3. The connection system 500 of FIG. 5 could be used with control panels 300 and/or the lockout/tagout features described above in conjunction with FIGS. 1-3.

In the connection system 500 of FIG. 5, the remote computer 140 is connected with the input port 142 of the network switching system 210, e.g., via an Ethernet cable 142C and/or other appropriate connection system (using any desired network communications protocols). The output port 212 of the network switching system 210 of this example is connected with an input/output port 130A of the universal processing computer 130. In this manner, when key switch 224 is closed, signals will be transferred between the remote computer 140 and the universal processing computer 130 through the network switching system 210. When key switch 224 is open, power to the network switching system 210 will be disconnected, and thus, no signals will be transferred between the remote computer 140 and the universal processing computer 130 through the network switching system 210. In the example of FIG. 5, the universal processing computer 130 is configured to perform EDA functions (rather than having this arrangement include a separate EDA computer connected with network switching system 202). If desired, however, a separate EDA computer could be provided in the arrangement shown in FIG. 5.

Input/output port 130B of the universal processing computer 130 in this example connection system 500 is connected to an input/output port 202A of the network switching system 202 (labeled “Port-1” in FIG. 5), e.g., via communication cable 132 (e.g., an Ethernet cable and/or other appropriate connection system (using any desired communications protocols)). Thus, remote computer 140 may be used to control one or more of substrate processing chambers 460, substrate handling chambers 402, 430, load-lock modules 410, 420, equipment front end module 440, and/or any other component parts of substrate processing system 400 via communications transmitted through the network switching system 210, the universal processing computer 130, and the network switching system 202.

Other connection system arrangements are possible in other examples of this technology. For example, connection systems 200 and 500 described above show the DC input ports of network switching system 202 and network switching system 210 connected by power line 222, with the key switch 224 provided in that power line 222 (between the DC power source 220 and the DC input port of network switching system 210). In this manner, power to the network switching system 210 can be controlled based on the position of the key switch 224, as described above. Other structures and options are possible. For example, if desired, separate power lines could be provided: (i) one between the DC power source 220 and network switching system 202 and (ii) another between DC power source 220 (or another DC power source) and network switching system 210, and a key switch 224 could be provided in either or both of these separate power lines to control power to network switching system 202 and/or network switching system 210. As another example, the key switch 224 shown in FIGS. 2 and 5 could be provided at a position in power line 222 to control power provided to network switching system 202 (rather than to network switching system 210). Note, for example the location shown by arrow A in FIGS. 2 and 5. As yet another example, the key switch 224 shown in FIGS. 2 and 5 could be provided at a position before the power line 222 to control power provided to both the network switching system 202 and the network switching system 210. Note, for example, the location shown by arrow B in FIGS. 2 and 5. Thus, a variety of different arrangements of the key switch 224 in the connection systems 200, 500 are possible in accordance with aspects of this technology.

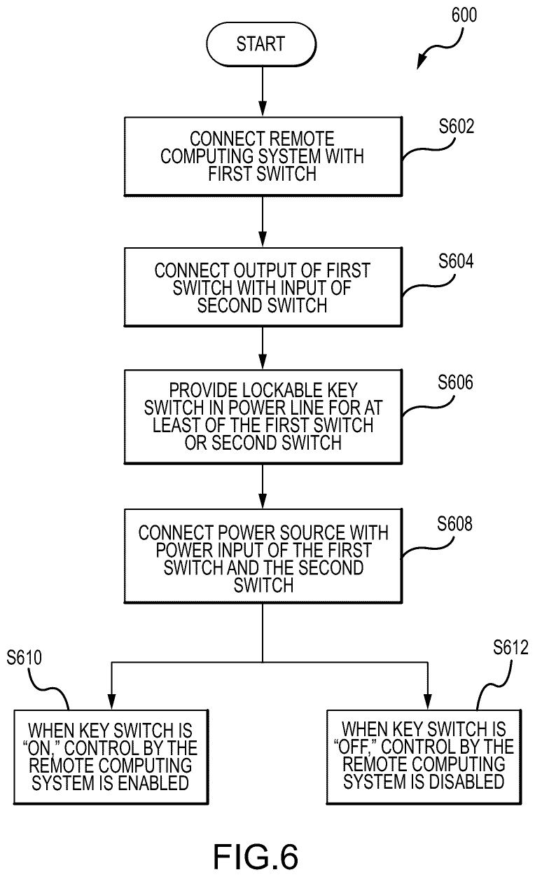

FIG. 6 provides a flow chart generally explaining processes 600 for set up and/or use of connection systems 200, 500 of the types described above (with additional reference to components shown in FIGS. 1-5). In such processes 600, a remote computer 140 is connected with an input port 142 of a first switching system 210, e.g., by an Ethernet cable 142C and/or other suitable network connection and/or communications protocol. Note step S602. At step S604, an output port 212 of the first switching system 210 is connected with an input port of a second switching system 202. In the connection system 200 of FIG. 2, this is a direct connection between output port 212 of the first switching system 210 and Port-1 of second switching system 202. In the connection system 500 of FIG. 5, this is an indirect connection, with output port 212 of the first switching system 210 connected with an input/output port 130A of universal processing computer 130 and input/output port 130B of universal processing computer 130 connected to Port-1 of second switching system 202. Ethernet connections and/or any other desired types of connectors and/or communications protocols may be used to make these connections. In these manners, the remote computer 140 is connectable to control the substrate processing systems 100, 400 through both the first switching system 210 and the second switching system 202.

At step S606, the process 600 further includes providing a lockable key switch 224 in a power line 222 for supplying power to at least one of the first switching system 210 and/or the second switching system 202. In the specific examples of FIGS. 1-5, the lockable key switch 224 is provided in a portion of power line 222 that supplies power to the first switching system 210. But, as discussed above with respect to arrows A and B in FIGS. 2 and 5, other locations for the lockable key switch 224 are possible in other specific examples of this technology.

Power line(s) 222 to the first switching system 210 and/or the second switching system 202 is/are connected to power source 220 (e.g., a DC power source) at step S608. Operation of the process 600 depends on the position of the lockable key switch 224. In the specific examples shown in FIGS. 2 and 5, a single power line 222 extends between the DC inputs of the first switching system 210 and the second switching system 202, and the output of power source 220 is connected (to supply power) to this power line 222 at step S608. When the lockable key switch 224 is in the “ON” position (see step S610), power is supplied to the first switching system 210 (and/or to the second switching system 202), which enables remote computer 140 to control the substrate processing systems 100, 400 (e.g., to control one or more of substrate processing chambers 104, 460; to control one or more of substrate handling chambers 102, 402, 430; and/or to control other equipment of the substrate processing systems 100, 400). When the lockable key switch 224 is in the “OFF” position (see step S612), power is disconnected from at least one of the first switching system 210 and/or the second switching system 202, which disables control of the substrate processing systems 100, 400 and/or its components by the remote computer 140. In the examples of FIGS. 2 and 5: (a) when the lockable key switch 224 is in the “ON” position (see step S610), power is supplied to the first switching system 210 and to the second switching system 202 via power line 222, and (b) when the lockable key switch 224 is in the “OFF” position (see step S612), power is disconnected from the first switching system 210. The second switching system 202 receives power from the DC power source 220 even when the key switch 224 is in the OFF position, in these specifically illustrated examples (although other arrangements are possible, as described above).

Other types of systems and/or methods of controlling remote access for operating substrate processing systems may be provided in accordance with other specific examples of this technology. For example, if desired, a key switch of the types described above (e.g., with a physical key 302 and lock) could be provided to control operation of (e.g., transmission of signals through) cable 142C (and, optionally, network switching system 210 could be omitted). Other types of locking hardware and/or software may be provided (e.g., for locking key switch 224 in the OFF position) to disable signals from remote computer 140 from reaching network switching system 202 and/or universal processing computer 130. Additionally or alternatively, other types of lockout and/or tagout hardware and/or software may be provided to disable signals from remote computer 140 from reaching network switching system 202 and/or universal processing computer 130 and for advising others who has created the lockout situation.

Substrate processing systems and methods in accordance with some examples of this technology may include other types of selectively activatable remote computer access, e.g., using lockout and/or tagout controls and/or features. Such substrate processing systems may include a lockable key switch (e.g., 224) of the types described above provided in a power supply line to any component necessary for transmitting data from the remote computer 140 to the substrate processing system equipment. Additionally or alternatively, a lockable key switch (e.g., 224) of the types described above may be provided in a data transmission line or connection for any component necessary for transmitting data from the remote computer 140 to the substrate processing system equipment (e.g., in an Ethernet cable such as cable 142C, operably connected to a wireless data transmission system, etc.). In such systems and methods, the lockable key switch (e.g., 224) may be movable between an “enabled” or ON position and a “disabled” or OFF position using a key (e.g., 302). When enabled or ON: (a) one or more electrical circuits including the power supply for supplying power to all required components for remote computer 140 control will be completed and/or (b) data transmission lines supplying data to all required components for remote computer 140 control will be completed, thereby enabling remote computer 140 control of the substrate processing system 100, 400. When disabled or OFF: (a) at least one electrical circuit including the power supply for supplying power to at least one required component for remote computer 140 control will be interrupted and/or (b) data transmission lines supplying data to at least one component for remote computer 140 control will be interrupted, thereby disabling remote computer 140 control of the substrate processing system 100, 400.

Thus, substrate processing systems and methods in accordance with some examples of this technology need not include the specific two network switching systems 202 and 210 structures described herein (e.g., network switching system 210 may be omitted if key switch 224 is placed at a different location to interrupt the power supply to a different component). But the two network switching systems 202 and 210 structures described herein may be advantageous in some examples of this technology as it disables remote computer 140 access while still allowing power and/or communications between the local components (e.g., between the universal processing computer 130 and the substrate processing chambers 104, 460 and/or other computers), which may be necessary and/or useful to complete the desired repair or service work.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing system, comprising:
a first switch including a first input port, a first power input, and a first output port;
a second switch including a first input/output port and a second power input;
a first electrical connector electrically connecting the first power input and the second power input;
a lockable key switch provided in the first electrical connector, the lockable key switch being movable between an off position and an on position;
a power source connected to the first electrical connector; and
a key configured to be received by the lockable key switch and configured to move the lockable key switch between the on position and the off position when received by the lockable key switch, wherein: (i) in the on position, the power source supplies power to the first switch and the second switch and (ii) in the off position, no power is supplied at least to the first switch.

2. The substrate processing system according to claim 1, wherein the key is removable from the lockable key switch only when the lockable key switch is in the off position.

3. The substrate processing system according to claim 1, wherein the first input port is configured to receive substrate processing commands from a remote computing system, and wherein the first output port is connected to the first input/output port of the second switch to transmit the substrate processing commands from the remote computing system, through the first switch, and to the second switch only when the lockable key switch is in the on position.

4. The substrate processing system according to claim 3, further comprising:
one or more substrate processing chambers in electronic communication with the second switch, wherein at least one of the one or more substrate processing chambers receives input data transmitted through the second switch based on the substrate processing commands received from the remote computing system only when the lockable key switch is in the on position.

5. The substrate processing system according to claim 1, further comprising a substrate processing system host computer, wherein the first input port is configured to receive substrate processing commands from a remote computing system, wherein the first output port is connected to the substrate processing system host computer and transmits the substrate processing commands from the remote computing system, through the first switch, and to the substrate processing system host computer only when the lockable key switch is in the on position, and wherein the substrate processing system host computer transmits signals to the first input/output port of the second switch based on the substrate processing commands received from the remote computing system.

6. The substrate processing system according to claim 5, further comprising:
one or more substrate processing chambers in electronic communication with the second switch, wherein at least one of the one or more substrate processing chambers receives input data transmitted through the second switch based on the substrate processing commands received from the remote computing system only when the lockable key switch is in the on position.

7. The substrate processing system according to claim 1, wherein the first input port comprises an ethernet port.

8. The substrate processing system according to claim 1, wherein the power source is a DC power source.

9. A substrate processing system, comprising:
a first switch including a first input port, a first power input, and a first output port;
a second switch including a first input/output port and a second power input, wherein the first output port is directly or indirectly connected with the first input/output port of the second switch;
a lockable key switch movable between an off position and an on position, the lockable key switch being provided in a power supply line connected to supply power to at least one of the first power input or the second power input; and
a key configured to be received by the lockable key switch and configured to move the lockable key switch between the on position and the off position when received by the lockable key switch, wherein: (i) in the on position, an electrical circuit including the power supply line for supplying power to at least one of the first power input or the second power input is completed and (ii) in the off position, the electrical circuit including the power supply line for supplying power to at least one of the first power input or the second power input is interrupted.

10. The substrate processing system according to claim 9, wherein the key is removable from the lockable key switch only when the lockable key switch is in the off position.

11. The substrate processing system according to claim 9, wherein the first input port is configured to receive substrate processing commands from a remote computing system, and wherein the first output port is directly connected to the first input/output port of the second switch to transmit the substrate processing commands from the remote computing system, through the first switch, and to the second switch only when the lockable key switch is in the on position.

12. The substrate processing system according to claim 11, further comprising:
one or more substrate processing chambers in electronic communication with the second switch, wherein at least one of the one or more substrate processing chambers receives input data transmitted through the second switch based on the substrate processing commands received from the remote computing system only when the lockable key switch is in the on position.

13. The substrate processing system according to claim 9, further comprising a substrate processing system host computer, wherein the first input port is configured to receive substrate processing commands from a remote computing system, wherein the first output port is connected to an input of the substrate processing system host computer and transmits the substrate processing commands from the remote computing system, through the first switch, and to the substrate processing system host computer only when the lockable key switch is in the on position, and wherein the substrate processing system host computer transmits signals to the first input/output port of the second switch based on the substrate processing commands received from the remote computing system.

14. The substrate processing system according to claim 13, further comprising:
one or more substrate processing chambers in electronic communication with the second switch, wherein at least one of the one or more substrate processing chambers receive input data transmitted through the second switch based on the substrate processing commands received from the remote computing system only when the lockable key switch is in the on position.

15. A method of connecting a substrate processing system with a remote computing system, comprising:
connecting a remote computing system with a first input port of a first switch, the first switch further including a first power input and a first output port;
directly or indirectly connecting the first output port of the first switch with a first input/output port of a second switch, the second switch further including a second power input;
electrically connecting the first power input and the second power input with an electrical connector that includes a lockable key switch, the lockable key switch being movable using a key between an off position and an on position; and
connecting a power source with the electrical connector, wherein the lockable key switch is provided in the electrical connector such that: (i) when the lockable key switch is in the on position, the power source supplies power to the first switch and the second switch, and (ii) when the lockable key switch is in the off position, no power is supplied to at least one of the first switch or the second switch by the power source.

16. The method according to claim 15, further comprising:
disabling operation of the substrate processing system by turning the lockable key switch from the on position to the off position using the key; and
removing the key from the lockable key switch.

17. The method according to claim 15, further comprising:
enabling operation of the substrate processing system by engaging the key with the lockable key switch while the lockable key switch is in the off position; and
turning the lockable key switch from the off position to the on position using the key.

18. A method of connecting a substrate processing system with a remote computing system, comprising:
connecting a remote computing system with a first input port of a first switch, the first switch further including a first power input and a first output port;
directly or indirectly connecting the first output port of the first switch with a first input/output port of a second switch, the second switch further including a second power input;
electrically connecting at least one of the first power input or the second power input with an electrical connector that includes a lockable key switch, the lockable key switch being movable using a key between an off position and an on position; and
connecting a power source with the electrical connector, wherein the lockable key switch is provided in the electrical connector such that: (i) when the lockable key switch is in the on position, the power source supplies power to at least one of the first switch or the second switch, and (ii) when the lockable key switch is in the off position, no power is supplied to at least one of the first switch or the second switch by the power source.

19. The method according to claim 18, further comprising:
disabling operation of the substrate processing system by turning the lockable key switch from the on position to the off position using the key; and
removing the key from the lockable key switch.

20. The method according to claim 18, further comprising:
enabling operation of the substrate processing system by engaging the key with the lockable key switch while the lockable key switch is in the off position; and
turning the lockable key switch from the off position to the on position using the key.
